(19) United States
(12) Patent Application Publication
(10) Pub. No.: US 2010/0168909 A1
(43) Pub. Date: Jul. 1, 2010

(54) Substrate Processing Apparatus

(75) Inventors: Mitsugu Sato, Tokyo (JP); Shigeo Kaneko, Tokyo (JP); Masayuki Nakayama, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kanagawa (JP)

(21) Appl. No.: 12/706,991

(22) Filed: Feb. 17, 2010

Related U.S. Application Data
(63) Continuation of application No. PCT/JP2008/065378, filed on Aug. 28, 2008.

(30) Foreign Application Priority Data
Aug. 31, 2007 (JP) 2007-226146

(51) Int. Cl. H01L 21/677; G06F 7/00

(52) U.S. Cl. 700/228

(57) ABSTRACT

A single-wafer substrate processing apparatus includes a substrate transfer chamber including a substrate transfer robot, a process chamber, connected to the substrate transfer chamber, for processing a substrate, and a plurality of port sets including (i) a load port, connected to the substrate transfer chamber for receiving an unprocessed substrate to be supplied to the substrate transfer robot, and (ii) an unload port connected to the substrate transfer chamber, as a member different from the load port, for receiving a processed substrate to be retrieved by the substrate transfer robot. Each of the plurality of port sets, the load port and the unload port are arranged adjacent to each other. The plurality of port sets is arranged apart from one another and around the substrate transfer chamber, and the load port and the unload port are adapted to be capable of vacuum exhaust and vacuum break independently of each other. A controller selects a port set to transfer a substrate using the substrate transfer robot, from among the plurality of port sets, and the unprocessed substrate is transferred one-by-one to the load port. When the unprocessed substrate is transferred to the load port, the inside of the load port is vacuum-exhausted, and when the processed substrate is transferred to the unload port, the inside of the unload port is vacuum-broken.

### CROSS-REFERENCES TO RELATED APPLICATIONS

This application is a continuation application of International Application No. PCT/JP2008/065378, filed on Aug. 28, 2008, the entire contents of which are incorporated by reference herein.

This application also claims the benefit of priority from Japanese Patent Application No. 2007-226146, filed Aug. 31, 2007, the entire contents of which are incorporated herein by reference.

### BACKGROUND OF THE INVENTION

1. Field of the Invention

The present invention relates to a single wafer load-lock-type substrate processing apparatus in a substrate processing apparatus for semiconductors, and the like.

2. Related Background Art

Conventionally, Japanese Published Unexamined Patent Application No. 2000-195920 and Japanese Published Unexamined Patent Application No. Hei 08-46013 disclose examples of a single-wafer substrate processing apparatus. In the substrate processing apparatuses shown in these patent documents, a plurality of process chambers is connected through gate valves to the periphery of a transfer chamber having a substrate transfer robot disposed therein, while two load lock chambers for transferring a substrate to or from the transfer chamber are connected through gate valves to the periphery of the transfer chamber, respectively. The load lock chamber is a chamber for introducing the substrates one-by-one into the transfer chamber or retrieving the substrates one-by-one from the transfer chamber. In the load lock chambers shown in these patent documents, a cassette capable of receiving a plurality of substrates is disposed. Here, the canying in/canying out of the substrate can be repeated until the inside of the cassette becomes empty or full, without breaking the vacuum of the inside of the chamber every time one substrate is introduced or retrieved.

### SUMMARY OF THE INVENTION

### Problems to be Solved by the Invention

When the substrate processing apparatuses are configured as described above, however, the volume of the load lock chamber is forced to be increased to some extent, because a space capable of receiving a plurality of substrates needs to be assured. Accordingly, if the vacuum is broken once at the time of exchanging cassettes, it takes time to evacuate the load lock chamber to a required pressure, thus resulting in a decrease in the throughput. It is an object of the present invention, therefore, to provide a substrate processing apparatus, a substrate manufacturing method, and a program that can achieve a higher throughput by efficient substrate transfer.

### Means for Solving the Problems

In order to achieve the above-described object, a substrate processing apparatus of the present invention is a single-wafer substrate processing apparatus comprising a plurality of load ports and a plurality of unload ports, wherein a substrate is transferred between the load ports and the unload ports, and a substrate transfer chamber, by a substrate transfer robot, and the apparatus further comprises a control section that recognizes an adjacent load port and an unload port among the respective load ports, and unload ports as a pair of ports at the time of transferring the substrate, and controls the substrate transfer robot to transfer the substrate to and from the pair of ports.

### EFFECTS OF THE INVENTION

According to the present invention, it is possible to achieve a high throughput by efficient substrate transfer.

### BRIEF DESCRIPTION OF THE DRAWINGS

FIG. 1 is a schematic plan view of a substrate processing apparatus of the present invention.

FIG. 2 is a control block diagram of the substrate processing apparatus of the present invention.

FIG. 3 is a wafer flow diagram in an embodiment of the present invention.

FIG. 4 is a flowchart in the embodiment of the present invention.

FIG. 5 is a composite diagram of FIG. 5A and FIG. 5B, which are wafer flow diagrams for illustrating the operation on an autoloader side.

FIG. 5A is a view of the first half portion of the wafer flow diagram for illustrating the operation on the autoloader side.

FIG. 5B is a view of the second half of the wafer flow diagram for illustrating the operation on the autoloader side.

FIG. 6A is a flowchart when a substrate transfer robot introduces a substrate or retrieves the substrate with respect to a load port or an unload port.

FIG. 6B is a flowchart when an autoloader robot introduces a substrate or retrieves the substrate with respect to the load port or the unload port.

### DESCRIPTION OF REFERENCE NUMERALS

3 substrate transfer chamber
5 substrate
6 load port
6A load port A
6B load port B
7 unload port
7A unload port A
7B unload port B
A, B port
P process chamber
Tr substrate transfer robot

### DESCRIPTION OF THE PREFERRED EMBODIMENTS

Next, the embodiments of the present invention will be described with reference to the accompanying drawings.

### First Embodiment

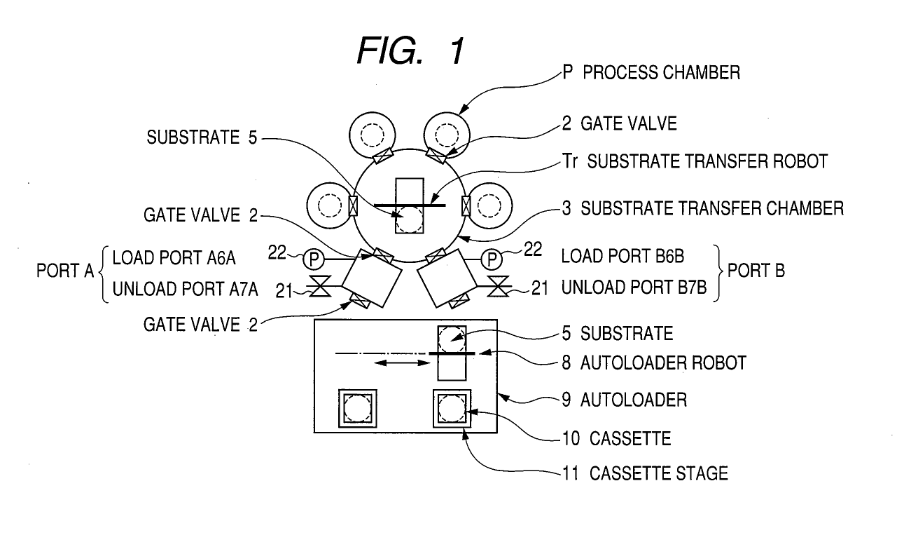

FIG. 1 is a schematic view showing a configuration example of a substrate transfer apparatus in a single-wafer substrate processing apparatus for semiconductors of this embodiment.

The substrate processing apparatus for semiconductors of this embodiment, which coats a substrate with a metal film by sputtering, is a single-wafer load lock type.

In this apparatus, a substrate transfer chamber incorporating a substrate transfer robot Tr in the center thereof is installed, and a plurality of process chambers P, which coat a substrate with a metal film by sputtering, is installed around the substrate transfer chamber 3. Note that any number of process chambers may be installed, depending on a device to manufacture, and furthermore, the types of the process chambers are not limited, such as a process chamber for CVD deposition, a process chamber for sputtering deposition, a process chamber for degasifying, or a process chamber for etching. The substrate transfer robot TR includes an arm capable of moving to a desired three-dimensional position, and an end effector capable of holding a substrate. Thus, the substrate transfer robot Tr is capable of supplying the substrates one-by-one into each of the process chambers P and retrieving the substrates one-by-one from each of the process chambers P.

Two load ports A6A, B6B and two unload ports A7A, B7B are installed around the substrate transfer chamber 3. Note that, since the load port and the unload port are arranged vertically, only one of them is shown in FIG. 1. The load port A6A and unload port A7A to be vertically arranged constitute a pair of ports (a port set) A, and similarly, another set of adjacent load port B6B and unload port B7B also constitutes a pair of ports (a port set) B. An unprocessed substrate is mounted in the load ports A6A, B6B and a processed substrate is mounted in the unload ports A7A, B7B. The respective load ports and unload ports are chambers each comprising a gate valve 2 that is provided so as to be hermetically connected to an autoloader 9 and the substrate transfer chamber 3, respectively, an atmosphere releasing valve 21 for introducing the atmospheric air inside the chamber, and a vacuum exhaust pump 22 for evacuating the inside of the chamber and other purposes, wherein these chambers are respectively adapted to independently enable evacuation and vacuum breaking. Moreover, the unload port includes a cooling mechanism for cooling a substrate and is capable of cooling a processed substrate, while the load port is provided with a heating mechanism for heating a substrate and is capable of, for example, degasifying prior to processing the substrate.

Moreover, a plurality of cassette stages 11 is arranged in front of the ports A, B. A cassette 10 is mounted on the cassette stage 11. The cassette stage 10 is a container capable of receiving a plurality of substrates, and a substrate 5 in the cassette 10 is transferred by an autoloader robot 8. The autoloader robot 8 transfers the substrate 5 in the cassette 10 to the load ports A6A, B6B, and transfers the substrate 5 in the unload ports A7A, B7B into the cassette 10. At this time, the autoloader robot moves in the horizontal direction, as illustrated, and comes to positions corresponding to the port A and the port B, respectively. Note that the autoloader robot 8 of FIG. 1 is capable of moving in front of a plurality of cassette stages 11 along a rail, and also includes an arm capable of moving to a desired three-dimensional position and an end effector capable of holding a substrate. Thus, the autoloader robot 8 is capable of transferring a substrate to and from among the respective load ports, unload ports, and cassette stages. Note that the configuration of the autoloader robot 8 is not limited thereto, and, for example, the configuration of the autoloader robot 8 may be one capable of retrieving and storing the substrate from/into the plurality of cassette stages 11 due to the movement of the arm.

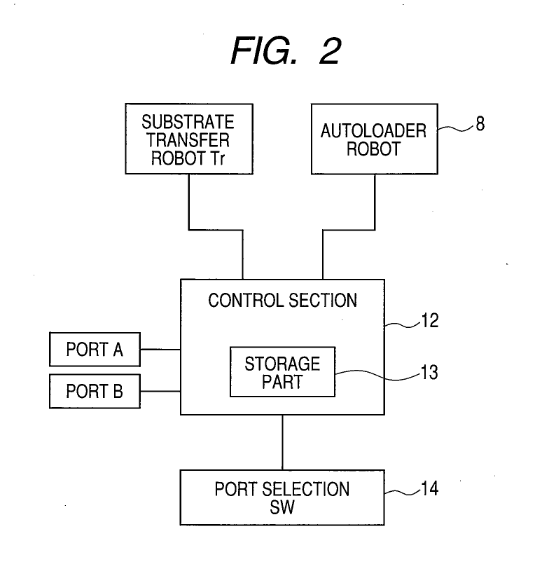

FIG. 2 is a control block diagram of the substrate processing apparatus for semiconductors for this embodiment.

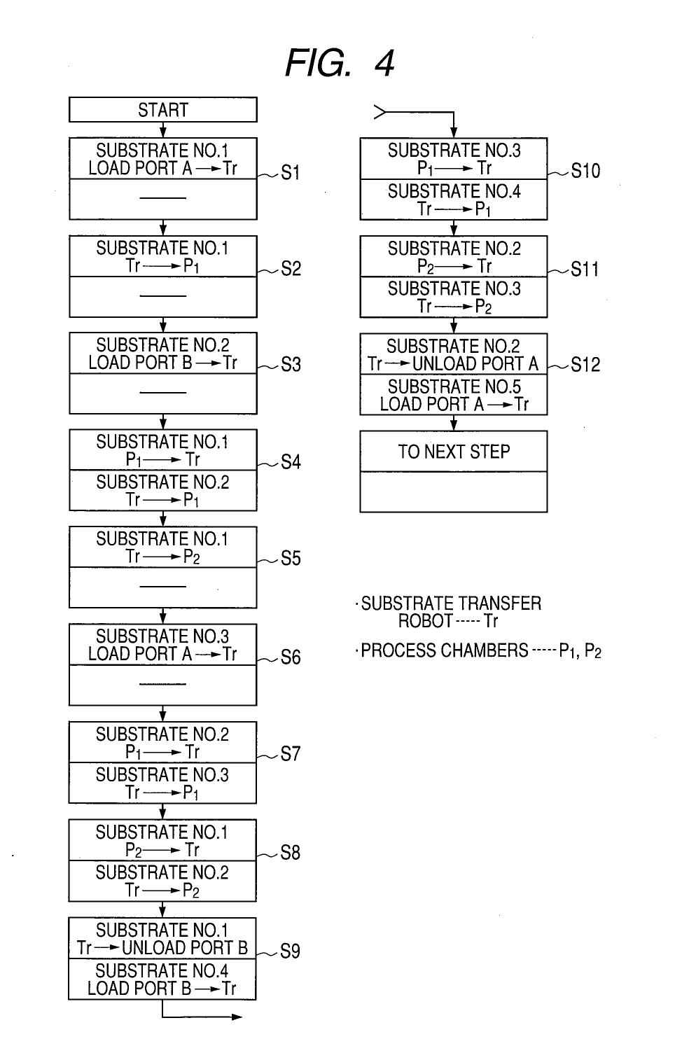

The substrate processing apparatus for semiconductors of this embodiment includes a control section 12 that controls the substrate transfer robot TR and the autoloader robot 8. That is, the control section 12 is a computer. The control section 12 includes a storage part 13, and, in the storage part 13, a program for executing a control flow of FIG. 4, described later, is stored. Moreover, the substrate processing apparatus for semiconductors of this embodiment includes a port selection SW 14 that operates only either one of the port A and the port B.

Next, the overview of a substrate transferring method in the single-wafer load lock type substrate processing apparatus is described. Note that, because the basic description of the substrate transfer is made here, the load port and the unload port are first described as the load port 6 or the unload port 7, without distinguishing between the load ports A6A and B6B or between the unload ports A7A and B7B.

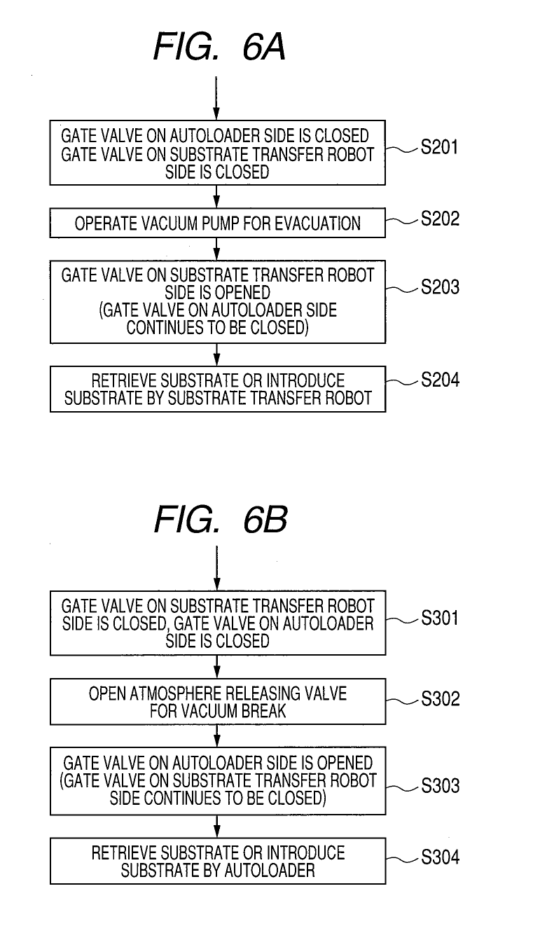

Moreover, the operation in the load port 6 and the unload port 7 at the time of the substrate supplying operation or substrate retrieving operation by the substrate transfer robot and the substrate supplying operation, or substrate retrieving operation by the autoloader robot, is shown as a flowchart in FIG. 6.

First, the cassette 10, having therein the unprocessed substrate 5, is placed on the cassette stage 11 of the autoloader 9, and the processing of the apparatus is started. The control section 12 controls the autoloader robot 8, so as to transfer the unprocessed substrates 5 in the cassette 10 one-by-one into the load port 6.

After completing the transfer of the unprocessed substrates 5 into the load port 6, the gate valve 2 engaging with the autoloader 9 of the front of the load port 6 is closed (FIG. 6A: Step S201), and the load port 6 is evacuated by the vacuum exhaust pump 22 (FIG. 6A: Step S202). Upon completion of the evacuation of the load port 6 to a predetermined pressure (on the order of 10⁻³ Pa), the gate valve 2 between the load port 6 and the substrate transfer chamber 3 is opened (FIG. 6A: Step S203). After the gate valve 2 is opened, the substrate 5 in the load port 6 is retrieved by the substrate transfer robot Tr (FIG. 6A: Step S204), and is then transferred into the substrate transfer chamber 3.

Upon completion of the transfer, the gate valve 2 between the load port 6 and the substrate transfer chamber 3 is closed, and the gate valve 2 between the substrate transfer chamber 3 and the process chamber P of the next step is opened. After the gate valve 2 is opened, the substrate 5 in the substrate transfer chamber 3 is transferred to this process chamber P by the substrate transfer robot Tr.

Upon completion of the transfer, the gate valve 2 between the process chamber P and the substrate transfer chamber 3 is closed. After the gate valve 2 is closed, a processing step of the process chamber P is started.

Upon completion of the processing of the first process chamber P, the substrate 5 in this process chamber P is transferred into the next process chamber P by the substrate transfer robot Tr, and, upon completion of the transfer, the processing in this process chamber P is performed. The same operation will be performed to a specified process chamber P.

Upon completion of the processings of all of the processing chambers P, the processed substrate 5 is transferred to the upload port 7 by the substrate transfer robot Tr. Upon completion of the transfer, the gate valve 2 between the substrate transfer chamber 3 and the unload port 7 is closed (FIG. 6B: S301). After the gate valve 2 is closed, the atmosphere releasing valve 21 is opened, to introduce the atmospheric air into the unload port 7, thereby breaking the vacuum of the unload port 7 (FIG. 6B: S302).

Once the inside of the unload port 7 is filled with the atmospheric air, the gate valve 2 in front of the unload port 7 is opened (FIG. 6B: S303), and the substrate 5 in the unload port 7 is transferred to the cassette 10 by the autoloader robot 8 (FIG. 6B: S304).

The same operation is repeated for the following second substrate 5, and the processings of a specified number of substrates 5 are continuously carried out.

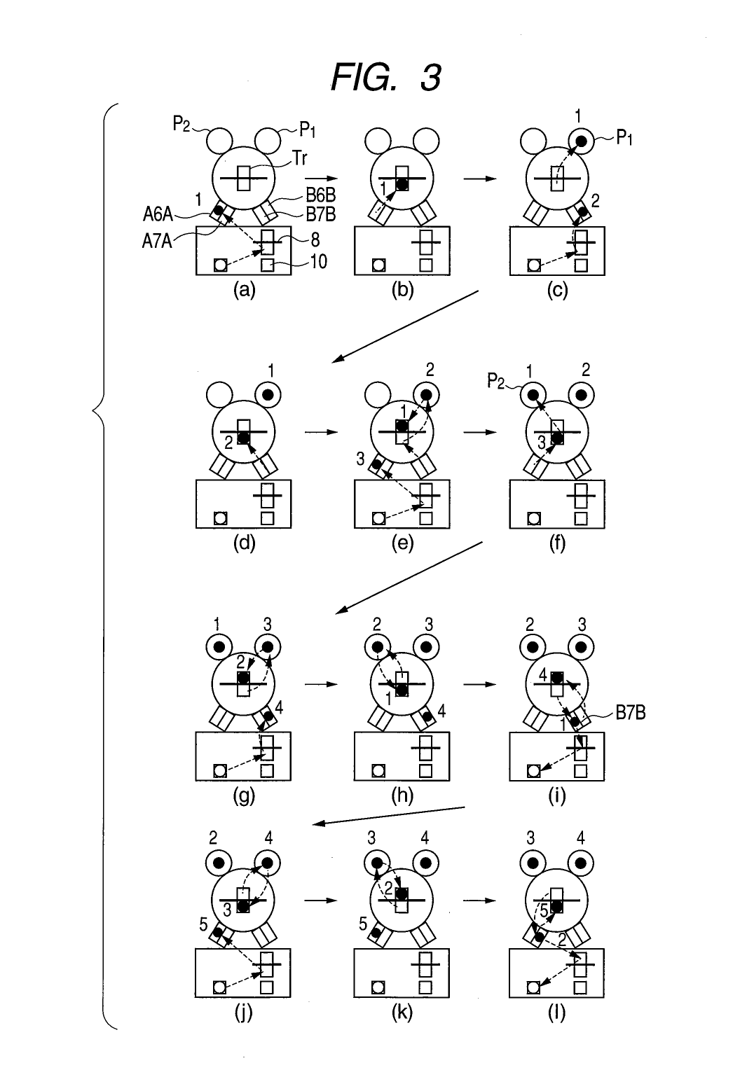

Next, more specific details of the substrate transferring method in the substrate processing apparatus for semiconductors of this embodiment will be described using FIG. 3 and FIG. 4.

FIG. 3 is a diagram schematically showing a substrate transfer process in the substrate processing apparatus for semiconductors of this embodiment. FIG. 4 is a flowchart for describing the substrate transfer process in the substrate processing apparatus for semiconductors of this embodiment. Note that, in FIG. 3, for ease of understanding of the arrangement of substrates, the vertically arranged load port and unload port are illustrated in a side-by-side arrangement.

Note that, for ease of description, the description is made with a number given to the substrate in the supplied order. That is, the substrate 5 to be first retrieved from the cassette 10 is given No. 1 and the next one is given No. 2.

In the following, the load port and the unload port are described as the load port A6A, B6B, or the unload port A7A, B7B, respectively. Here, two process chambers P are denoted as a process chamber P1 and a process chamber P2.

First, the No. 1 substrate 5 in the cassette 10 is transferred to the load port A6A by the autoloader robot 8 (FIG. 3(a)). The substrate 5 of the load port A6A is retrieved by the substrate transfer robot Tr (FIG. 3(b), (Step S1)), and is then transferred into the process chamber P1 (FIG. 3(c), (Step S2)). At this time, the No. 2 substrate 5 in the cassette 10 is transferred to the load port B6B by the autoloader robot 8 (FIG. 3(c)). Although the left or right movement of the autoloader robot 8 is not shown in FIG. 3, the autoloader robot 8 transfers the substrate by moving back and forth between the cassette stages 11 on both sides, and the port sets on both sides.

Next, the substrate transfer robot Tr retrieves the No. 2 substrate 5 of the load port B6B (FIG. 3(d), (Step S3)).

The substrate transfer robot Tr retrieves the No. 1 substrate 5 that has been subjected to the processing in the process chamber P1, and transfers the No. 2 substrate 5 to the process chamber P1 (FIG. 3(e), (Step S4)). Moreover, the No. 3 substrate 5 in the cassette 10 is transferred to the load port A6a by the autoloader robot 8 (FIG. 3(e)).

The substrate transfer robot Tr transfers the No. 1 substrate 5 to the process chamber P2 (FIG. 3(f), Step S5), and retrieves the No. 3 substrate 5 of the load port A6a (FIG. 3(f), (Step S6)).

Next, the substrate transfer robot Tr retrieves the No. 2 substrate 5 that has been subjected to the processing in the process chamber P1, and transfer the No. 3 substrate 5 to the process chamber P1 (FIG. 3(g), (Step S7)). Moreover, the No. 4 substrate 5 in the cassette 10 is transferred to the load port B6B by the autoloader robot 8.

The substrate transfer robot Tr retrieves the No. 1 substrate 5 that has been subjected to the processing in the process chamber P2, and transfers the No. 2 substrate 5 to the process chamber P2 (FIG. 3(h), (Step S8)).

The substrate transfer robot Tr transfers to the unload port B7B the No. 1 substrate 5 that has been subjected to the processings in the respectively process chambers P1, P2, and also retrieves the No. 4 substrate 5 from the load port B6B (FIG. 3(i), (Step S9)).

Here, as the method of returning the processed No. 1 substrate to the unload port, it is also contemplated to transfer the processed No. 1 substrate to the unload port A7A on the port A side where the No. 1 substrate was introduced. However, in this case, in order to retrieve the No. 4 substrate 5 stored in the load port B6B, the step of changing the direction of the substrate transfer robot Tr will occur.

In contrast, in the control method of this embodiment, the transfer of the processed substrate 5 and the transfer of the substrate 5 to be processed can be performed in the same step. The control section 12 recognizes the adjacent load port and unload port as a pair of ports at the time of transferring the substrate to and from among the load port, the unload port, and the substrate transfer chamber. That is, in the case of this embodiment, the control section 12 recognizes the adjacent load port B6B and unload port B7B as a pair of ports B. Then, the processed substrate 5 is transferred to the unload port B7B, and the unprocessed substrate 5 is retrieved from the load port B6B. Since the load port B6B and the unload port B7B are adjacent to each other, the substrate transfer robot Tr does not need to change the direction thereof at the time of transferring the substrates 5. Therefore, according to the control method of this embodiment, the transfer of the processed substrate 5 and the transfer of the unprocessed substrate 5 can be performed in the same step.

Furthermore, the autoloader robot 8 retrieves the No. 1 substrate 5 in the unload port B7B (FIG. 3(i)).

Next, the substrate transfer robot Tr retrieves the No. 3 substrate 5 that has been subjected to the processing in the process chamber P1, and transfers the No. 4 substrate 5 to the process chamber P1 (FIG. 3(j), (Step S10)). Moreover, the No. 5 substrate 5 in the cassette 10 is transferred to the load port A6A by the autoloader robot 8 (FIG. 3(j)).

The substrate transfer robot Tr retrieves the No. 2 substrate 5 that has been subjected to the processing in the process chamber P2, and transfers the No. 3 substrate 5 to the process chamber P2 (FIG. 3(k), (Step S11)).

The substrate transfer robot Tr transfers to the unload port A7A the No. 2 substrate 5 that has been subjected to the processing in the respective process chambers P1, P2 (FIG. 3(l), (Step S12)). In this case, the control section 12 recognizes the adjacent load port A6A and unload port A7A as a pair of ports A. Then, the processed substrate 5 is transferred to the unload port A7A, and the unprocessed No. 5 substrate 5 is retrieved from the load port A6A. Since the load port A6A and the unload port A7A are adjacent to each other, the substrate transfer robot Tr does not need to change the direction thereof at the time of transferring the substrates 5. Therefore, the transfer of the processed No. 2 substrate 5 and the transfer of the unprocessed No. 5 substrate 5 can be performed in the same step.

Furthermore, although the autoloader robot 8 retrieves the No. 2 substrate 5 in the unload port A7A (FIG. 3(l)), the autoloader robot 8 does not need to be moved, because the processed substrate 5 and the unprocessed substrate 5 are stored in the same port A.

Hereafter, the same steps will be repeated.

As described above, according to the control method of this embodiment, since the step of changing the direction of the substrate transfer robot Tr does not occur even if the number of process chambers P is either of an odd number and an even number, the throughput will not decrease.

Next, the function of the port selection switch 14 is described.

The control section 12 recognizes the adjacent load port and unload port as a pair of ports. That is, for example, when the control section 12 recognizes the adjacent load port A6A and unload port A7A as a pair of ports A, the substrate processing apparatus of the present invention can perform the transfer of the processed substrate 5 and the transfer of the unprocessed substrate 5 only with the port A without using the port B.

The port selection switch 14 can select either the port A or the port B. Therefore, when the port A is selected by the port selection switch 14, the substrate is processed using only the port A.

Therefore, for example, when the port A is selected by the port selection switch 14, the maintenance of the port B not in use can be performed while operating the apparatus. Moreover, according to the present invention, when trouble has occurred in either one of the ports, a normally operating port is selected by the port selection switch 14, so that the processing can be continued only with this port without stopping the apparatus. Then, the port where the trouble has occurred can be fixed during this time.

As described above, since the substrate processing apparatus of the present invention allows for maintenance and repair without stopping the apparatus, the operating rate of the apparatus can be increased.

### Second Embodiment

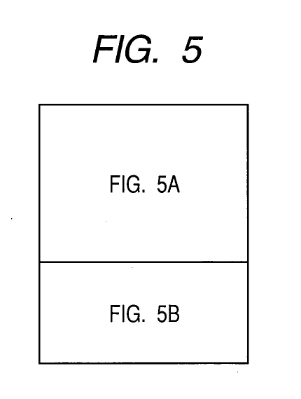

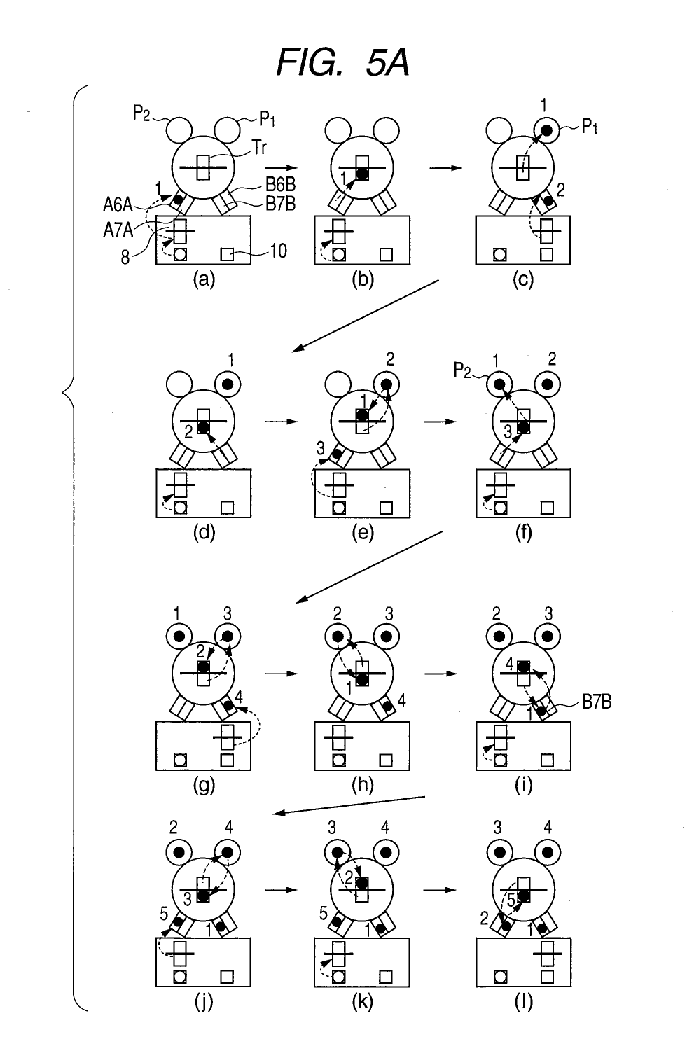

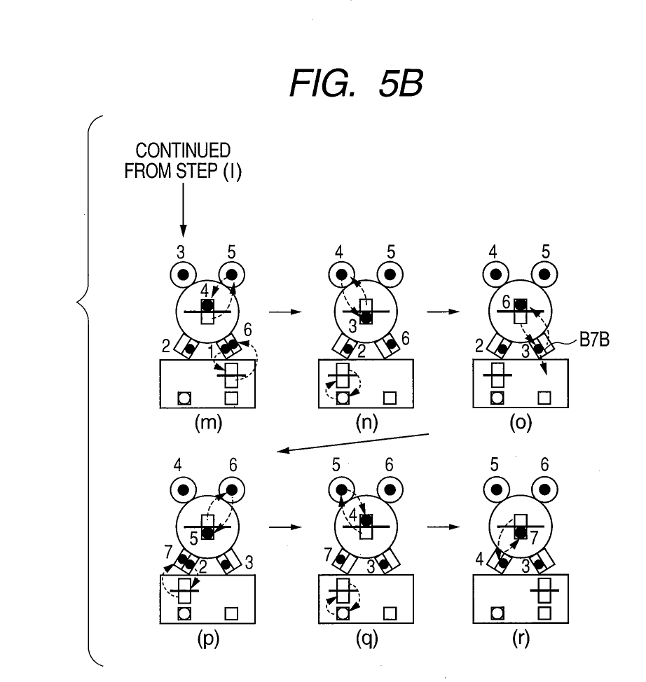

Next, the substrate supplying and retrieving operation on the autoloader robot 8 side in a wafer flow similar to the wafer flow diagram shown in FIG. 3 is described specifically. FIG. 5 shows the operation of the autoloader robot 8 in detail. Note that the description of the same part as that of FIG. 3 is omitted.

As shown in FIG. 5, the autoloader robot 8 alternatively supplies the No. 1 to No. 4 substrates to the load ports A, B (FIGS. 5(a) to 5(g)). By alternately supplying in this manner, for example, when one of the load ports is evacuated in order to supply a substrate to the substrate transfer robot Tr and then, before the vacuum of this chamber is broken in order to receive substrate supply from the autoloader robot 8, a substrate can be supplied to the other load port concurrently. Therefore, the tact time can be reduced and the throughput can be increased.

Upon completion of the supply of the No. 1 to No. 4 substrates, the No. 1 substrate is processed and thereafter, is retrieved to the unload port B6B (FIG. 5(i)), and the substrate transfer robot Tr places the No. 4 substrate, which has been placed on the load port B, on the emptied end effector and retrieves the same. As described above, this makes it possible to continuously perform the substrate retrieving operation and the substrate supplying operation without the arm rotating wastefully.

Here, although the substrate having been retrieved to the unload port B may be retrieved by the autoloader robot 8, a vacuum break needs to be performed on the evacuated unload port B6B. Then, in the second embodiment, during this period, or prior to this period, i.e., after the autoloader robot 8 supplies the No. 4 substrate to the load port B6B, the No. 5 substrate is supplied to the load port A6A (FIG. 5(j)).

Next, the autoloader robot 8 retrieves the No. 6 substrate from the substrate cassette (FIG. 5(k)), and supplies the same to the load port B6B (FIG. 5(m)). Subsequently, the autoloader robot 8 retrieves the No. 1 substrate that has been retrieved to the unload port B7B. Thereby, the substrate retrieving operation and substrate supplying operation can be continuously performed also on the autoloader 9 side, so that a wasteful operation can be omitted, to increase the throughput.

The rest of the steps are the same as those described earlier. The autoloader robot 8 moves back and forth alternately between the ports A, B, so that the substrate retrieving operation and supplying operation can be performed.

Note that the application of the present invention is not limited to the first and second embodiments described above, and, for example, the autoloader robot 8 may be provided for each port. However, by operating as described with respect to the above-described embodiments, the substrate can be retrieved in supplied order or in processed order, thereby facilitating the management of the substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A single-wafer substrate processing apparatus comprising:
a substrate transfer chamber including a substrate transfer robot;
a process chamber, connected to the substrate transfer chamber, for processing a substrate;
a plurality of port sets including (i) a load port, connected to the substrate transfer chamber, and capable of receiving an unprocessed substrate to be supplied to the substrate transfer robot, and (ii) an unload port connected to the substrate transfer chamber, as a member different from the load port, and capable of receiving a processed substrate to be retrieved by the substrate transfer robot, wherein in each of the plurality of port sets, the load port and the unload port are arranged adjacent to each other, the plurality of port sets is arranged apart from one another and around the substrate transfer chamber, and the load port and the unload port are adapted to be capable of vacuum exhaust and vacuum break independently of each other; and
a controller that selects a port set to transfer a substrate using the substrate transfer robot, from among the plurality of port sets, the unprocessed substrate being transferred one-by-one to the load port,
wherein, when the unprocessed substrate is transferred to the load port, the inside of the load port is vacuum-exhausted, and when the processed substrate is transferred to the unload port, the inside of the unload port is vacuum-broken.

2. A substrate processing apparatus according to claim 1, further comprising an autoloader that supplies an unprocessed substrate to the load port and retrieves a processed substrate from the unload port.

3. A substrate processing apparatus according to claim 2, wherein the autoloader transfers the substrates one-by-one between the load port and the unload port.

4. A substrate processing apparatus according to claim 2, wherein the autoloader is commonly provided for the plurality of port sets.

5. A substrate processing apparatus according to claim 1, wherein the controller selects a port set for each substrate supply timing from the load port, so that a substrate is supplied from the load port of the port set different from one used most recently, and the controller concurrently causes the load port which has supplied the substrate most recently to prepare for supplying the substrate.

6. A substrate processing apparatus according to claim 5, wherein, when substrate retrieval to the unload port and substrate supply from the load port are continuous, the controller selects a port set so that the retrieval and the supply are continuously performed from the same port set.

7. A substrate processing apparatus according to claim 1, wherein the load port and the unload port respectively include independently controlled evacuation devices.

8. (canceled)
